(19) United States
(12) Patent Application Publication
(10) Pub. No.: US 2020/0075524 A1
(43) Pub. Date: Mar. 5, 2020

(54) SEMICONDUCTOR DEVICE HAVING BUMP STRUCTURES AND SEMICONDUCTOR PACKAGE HAVING THE SAME

(71) Applicant: Samsung Electronics Co., Ltd., Suwon-si (KR)

(72) Inventors: Ju Bin SEO, Hwasung-si (KR); Dong Hoon LEE, Hwasung-si (KR); Ju Il CHOI, Hwasung-si (KR); Su Jeong PARK, Hwasung-si (KR); Dong Chan LIM, Hwasung-si (KR)

(73) Assignee: Samsung Electronics Co., Ltd., Suwon-si (KR)

(21) Appl. No.: 16/356,224

(22) Filed: Mar. 18, 2019

(30) Foreign Application Priority Data
Aug. 29, 2018 (KR) 10-2018-0102091

(51) Int. Cl. H01L 23/00; H01L 23/48

(52) U.S. Cl. CPC H01L 24/13; H01L 2224/11848; H01L 24/14; H01L 24/16; H01L 24/17; H01L 23/481; H01L 2224/1357; H01L 2224/13611; H01L 2224/13644; H01L 2224/13647; H01L 2224/13582; H01L 2224/14181; H01L 2224/16145; H01L 2224/16503; H01L 2224/17181; H01L 2224/1146; H01L 2224/11912; H01L 2224/11825; H01L 24/11

(57) ABSTRACT

A semiconductor device including a substrate including a first conductive pad on a first surface thereof, at least one first bump structure on the first conductive pad, the first bump structure including a first connecting member and a first delamination prevention layer, the first delamination prevention layer on the first connecting member and having a greater hardness than the first connecting member, and a first encapsulant above the first surface of the substrate and surrounding the first bump structure may be provided.

### CROSS-REFERENCE TO RELATED APPLICATION

This application claims priority to Korean Patent Application No. 10-2018-0102091, filed on Aug. 29, 2018, in the Korean Intellectual Property Office (KIPO), the disclosure of which is incorporated herein by reference in its entirety.

### BACKGROUND

### Field

Some example embodiments relate to semiconductor devices having a bump structure and/or semiconductor packages including the same.

### Description of Related Art

Due to demands for more compact and lightweight semiconductor devices, methods of reducing the size of bumps have become important in semiconductor package technology. For example, micro-bumps having a small size are formed between semiconductor chips with a fine pitch. The micro-bumps having a smaller size and/or improved reliability are desired. Since a solder used for bonding different bumps may be delaminated in a manufacturing process, a technique for protecting the bumps is also desired.

### SUMMARY

Some example embodiments of the inventive concepts are directed to providing semiconductor devices including a bump structure that is capable of mitigating or preventing delamination of a connecting member.

Further, some example embodiments of the inventive concepts are directed to providing semiconductor packages including a bump structure that is capable of mitigating or preventing delamination of a connecting member.

According to an example embodiment, a semiconductor device includes a substrate including a first conductive pad on a first surface thereof, at least one first bump structure on the first conductive pad, the first bump structure including a first connecting member and a first delamination prevention layer, the first delamination prevention layer on the first connecting member and having a greater hardness than the first connecting member, and a first encapsulant above the first surface of the substrate and surrounding the first bump structure.

According to an example embodiment, a semiconductor package includes a first semiconductor device including a first conductive pad, at least one first bump structure on the first conductive pad, and a first encapsulant surrounding the first bump structure, which are sequentially stacked on an upper surface of a first substrate, the first bump structure including a first connecting member and a first delamination prevention layer, the first delamination prevention layer on the first connecting member and having a greater hardness than the first connecting member, a side surface of the first delamination prevention layer and a side surface of the first connecting member being coplanar, and a second semiconductor device including a second conductive pad, at least one second bump structure under the second conductive pad, a second encapsulant surrounding the second bump structure, which are sequentially stacked on a lower surface of a second substrate, the second bump structure including a second connecting member and a second delamination prevention layer, the second delamination prevention layer on the second connecting member and having a greater hardness than the second connecting member, a side surface of the second delamination prevention layer and a side surface of the second connecting member being coplanar, the second bump structure being in contact with the first bump structure.

According to an example embodiment, a semiconductor package includes a plurality of stacked semiconductor devices and each of the plurality of stacked semiconductor devices includes a substrate including conductive pads on one surface or two opposite surfaces thereof, bump structures each including a connecting member and a delamination prevention layer, the delamination prevention layer being on the connecting member and having a greater hardness than the connecting member, and one or more inner encapsulants on the one surface or the two opposite surfaces of the substrate and surrounding the bump structures, each of the plurality of stacked semiconductor devices being in contact with and immediately adjacent to one or more of the plurality of stacked semiconductor devices, and an external encapsulant sealing the plurality of stacked semiconductor devices.

### BRIEF DESCRIPTION OF THE DRAWINGS

FIG. 1 is a cross-sectional view showing a semiconductor device according to an example embodiment of the inventive concepts.

FIG. 2 is an enlarged view showing a region ‘II’ of the semiconductor device of FIG. 1, according to an example embodiment of the inventive concepts.

FIGS. 3 and 4 are enlarged views showing the region ‘II’ of the semiconductor device of FIG. 1, according to some other example embodiments of the inventive concepts.

FIGS. 5 and 6 are cross-sectional views showing a semiconductor device, according to some example embodiments of the inventive concepts.

FIG. 7 is an enlarged cross-sectional view showing a portion of a semiconductor package in which semiconductor devices are stacked, according to an example embodiment of the inventive concepts.

FIG. 8 is a cross-sectional view showing a portion of a semiconductor package in which semiconductor devices are stacked, according to another example embodiment of the inventive concepts.

FIGS. 9 to 18 are cross-sectional views showing a process sequence for describing a method of manufacturing a semiconductor device, according to an example embodiment of the inventive concepts.

FIGS. 19 ad 20 are cross-sectional views showing a process sequence for a method of manufacturing a semiconductor device according to another example embodiment of the inventive concepts.

FIG. 21 is a cross-sectional view showing a semiconductor package, according to an example embodiment of the inventive concepts.

### DETAILED DESCRIPTION

While the term “same” is used in description of example embodiments, it should be understood that some imprecisions may exist. Thus, when one element is referred to as being the same as another element, it should be understood that the one element is the same as another element within a desired manufacturing the tolerance range (e.g., ±10%).

When the terms “about” or “substantially” are used in this specification in connection with a numerical value, it is intended that the associated numerical value includes a manufacturing tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure.

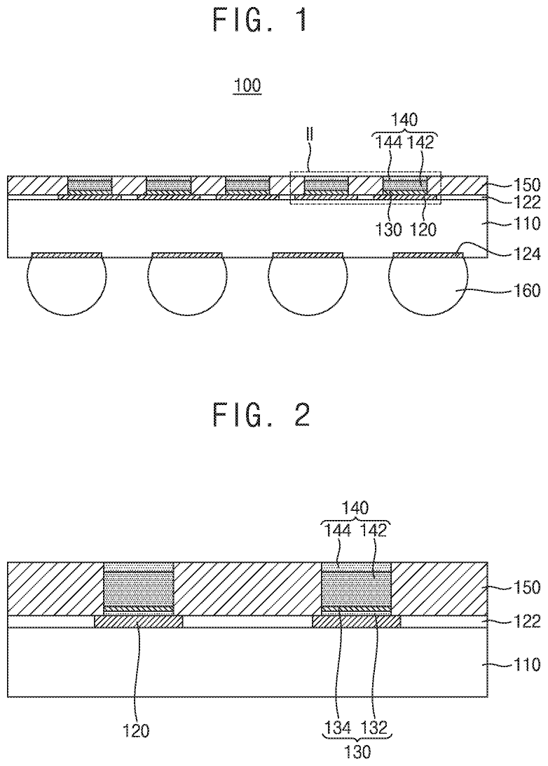

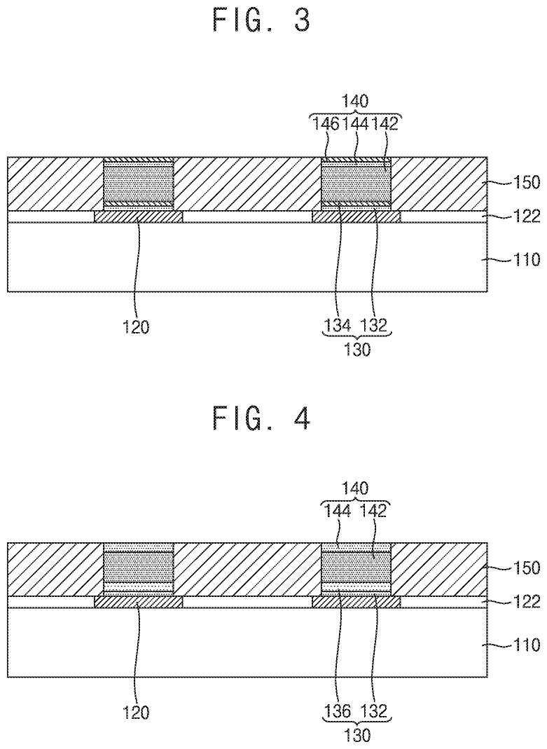

FIG. 1 is a cross-sectional view showing a semiconductor device according to an example embodiment of the inventive concept. FIG. 2 is an enlarged view showing a region ‘II’ of the semiconductor device of FIG. 1, according to an example embodiment of the inventive concepts.

Referring to FIGS. 1 and 2, a semiconductor device 100 according to the example embodiment of the inventive concepts may include a substrate 110, conductive pads 120 and 124, under bump metals 130, bump structures 140, and an encapsulant 150. The semiconductor device 100 may be a memory chip or a logic chip. The semiconductor device 100 may further include external terminals 160 thereunder. A protective layer 122 may be further disposed on the substrate 110. The under bump metal 130 may include a barrier layer 132 and a seed layer 134. The bump structure 140 may include a connecting member 142 and a delamination prevention layer 144.

The substrate 110 may include the conductive pads 120, the conductive pads 124, and the protective layer 122. In an example embodiment, the substrate 110 may include a semiconductor (e.g., silicon (Si) or germanium (Ge)), a compound semiconductor (e.g., SiC, GaAs, GaP, InAs, AlGaN, AlGaAs, GaInP, or a combination thereof). In an example embodiment, the substrate 110 may include a silicon-on-insulator (SOI) substrate and an amorphous substrate. The substrate 110 may have an upper surface and a lower surface opposite to each other.

The conductive pads 120 may be disposed on the upper surface of the substrate 110, and the conductive pads 124 may be disposed on the lower surface of the substrate 110. The conductive pads 120 and 124 may be electrically connected to each other. The conductive pads 120 and 124 may include metal (e.g., copper). The conductive pad 120 may be electrically connected to the external terminal 160 through the conductive pad 124.

The protective layer 122 may be disposed on the upper surface of the substrate 110. The protective layer 122 may be disposed on side surfaces of the conductive pads 120 and an upper end of the protective layer 122 may be positioned at substantially the same level as upper ends of the conductive pads 120.

The under bump metal 130 may be disposed on the conductive pad 120. The under bump metal 130 may have a smaller thickness than the conductive pad 120. The under bump metal 130 may be a single layer or a multilayer. In an example embodiment, the under bump metal 130 may include the barrier layer 132 and the seed layer 134. The barrier layer 132 may be disposed on an upper surface of the conductive pad 120, and the seed layer 134 may be disposed on an upper surface of the barrier layer 132. The barrier layer 132 may mitigate or prevent the metal contained in the conductive pad 120 from being diffused into the connecting member 142. The seed layer 134 may provide a seed in a plating process for forming the connecting member 142.

The bump structure 140 may be disposed on the under bump metal 130. When semiconductor devices 100 are stacked, the bump structures 140 may electrically connect the semiconductor devices 100 to each other. The bump structure 140 may have a planarized upper surface, and the upper surface of the bump structure 140 may be exposed to the outside of the first encapsulant 150. The bump structure 140 may include the connecting member 142 and the delamination prevention layer 144 which are sequentially stacked. The connecting member 142 may have a rectangular shape when viewed from the side (in other words, when viewed in a cross-section). The connecting member 142 may have a circular shape, a square shape, a rectangular shape, or an elliptical shape when viewed from above, but the inventive concepts are not limited thereto. The connecting member 142 may include tin (Sn). The delamination prevention layer 144 may be disposed on the connecting member 142. The delamination prevention layer 144 may have a thickness smaller than the connecting member 142, and may have a greater hardness than the connecting member 142. In an example embodiment, the delamination prevention layer 144 may include an intermetallic compound (IMC). For example, the delamination prevention layer 144 may include a Cu—Sn based metal compound (e.g., Cu₃Sn₄ or Cu₆Sn₅), an Au—Sn based IMC (e.g., AuSn, AuSn₂, AuSn₄, or Au₅Sn), a Sn—Ag based IMC (e.g., Ag₃Sn), or a combination thereof.

The encapsulant 150 may be disposed on the upper surface of the substrate 110 and side surfaces of the bump structures 140. The encapsulant 150 may be formed to surround the bump structures 140 to protect the bump structures 140 from external influences such as impact. The encapsulant 150 may be planarized such that an upper surface of the encapsulant 150 may be coplanar with the upper surfaces of the bump structures 140. The encapsulant 150 may include, for example, an epoxy molding compound (EMC).

The external terminals 160 may be disposed on the lower surface of the substrate 110. The external terminal 160 may be electrically connected to the conductive pad 124. The external terminal 160 may mediate an electrical signal between the semiconductor device 100 and the outside. For example, the external terminal 160 may receive a control signal, a power supply signal, a ground signal, and/or a data signal for controlling an operation of the semiconductor device 100 from the outside, or may receive a data signal from the semiconductor device 100. The external terminal 160 may be a controlled collapse chip connection (C4) bump, and may include tin (Sn).

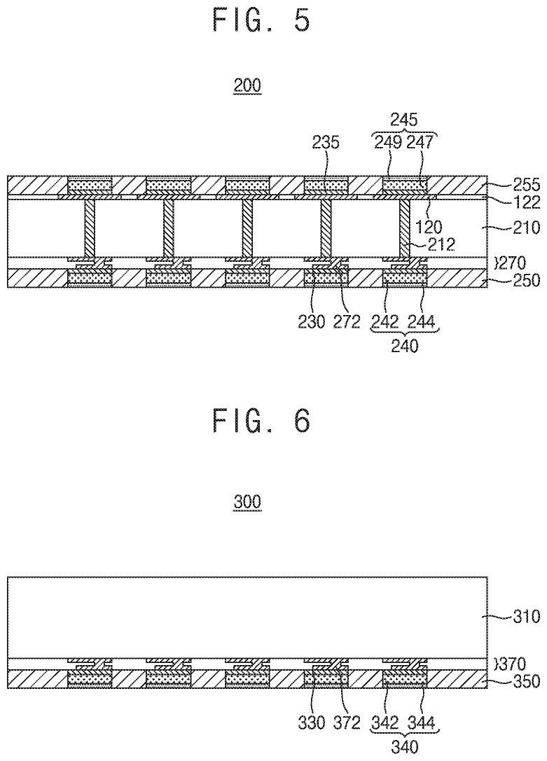

FIGS. 3 and 4 are enlarged views showing the region ‘II’ of the semiconductor device 100 according to some other example embodiments of the inventive concepts. FIGS. 3 and 4 may correspond to the example embodiment of FIG. 2 and a detailed description of the same components as those of FIG. 2 may be omitted.

Referring to FIG. 3, a delamination prevention layer 144 may further include a metal layer 146 thereon. The metal layer 146 may have a higher hardness than the delamination prevention layer 144. The metal layer 146 may have a planarized upper surface, and the upper surface of the metal layer 146 may be coplanar with an upper surface of an encapsulant 150. In a manufacturing process to be described below, after the metal layer 146 is formed on a connecting member 142, a thermal treatment process and a molding process may be performed. The metal layer 146 may be diffused into the connecting member 142 by a thermal treatment process, and thus may be phase-transitioned to an IMC. In an example embodiment, the metal layer 146 shown in FIG. 3 may be a remaining portion of the metal layer 146 that is not diffused into the connecting member 142 after the thermal treatment process. In an example embodiment, the metal layer 146 may be subjected to a molding process without being subjected to a thermal treatment process. In such an example embodiment, the delamination prevention layer 144 may be the IMC which is naturally formed between the metal layer 146 and the connecting member 142.

As shown in FIG. 3, when the metal layer 146 is formed on the connecting member 142, the metal layer 146 has a greater hardness than the connecting member 142, and thus delamination of the connecting member 142 may be mitigated or prevented in a planarization process.

Referring to FIG. 4, an under bump metal 130 may include an IMC layer 136. The IMC layer 136 may be formed by metallization of the seed layer 134 and the connecting member 142. For example, the IMC layer 136 may include Cu₃Sn₄ or Cu₆Sn₅. The IMC layer 136 may have a thickness greater than the seed layer 134. In FIG. 4, the entire seed layer 134 is shown as being phase-transitioned to the IMC layer 136 by a chemical reaction. However, in an example embodiment, the seed layer 134 may remain at a lower portion of the IMC layer 136.

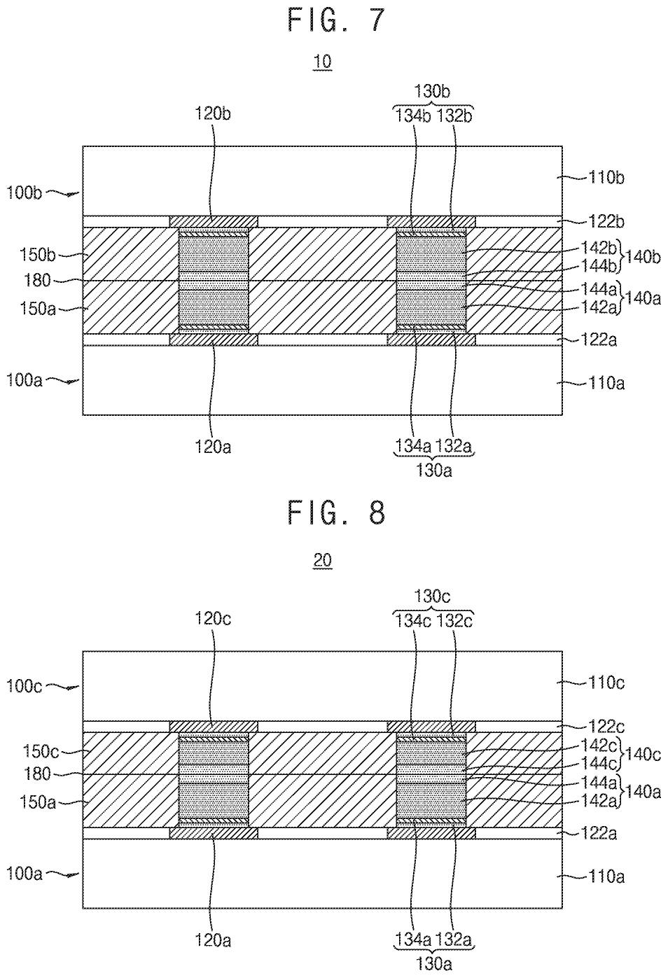

FIGS. 5 and 6 are cross-sectional views showing semiconductor devices 200 and 300 according to some example embodiments of the inventive concepts.

FIG. 5 may correspond to the example embodiment of the semiconductor device 100 shown in FIG. 1. Referring to FIG. 5, the semiconductor device 200 may include under bump metals 230, bump structures 240, an encapsulant 250, and an element layer 270, which are disposed under a substrate 210. Further, the semiconductor device 200 may include conductive pads 120, a protective layer 122, under bump metals 235, bump structures 245, and an encapsulant 255, which are disposed above the substrate 210. The conductive pads 120, the protective layer 122, the under bump metals 235, the bump structures 245, and the encapsulant 255 may have technical features and structures identical or substantially similar to those of the conductive pads 120, the protective layer 122, the under bump metals 130, the bump structures 140, and the encapsulant 150, which are shown in FIG. 2.

The substrate 210 may further include a plurality of through silicon vias (TSVs) 212 that are spaced by a desired (or alternatively, predetermined) distance from each other. The TSV 212 may pass through at least a portion of the substrate 210 and vertically extend. The plurality of TSVs 212 may be disposed in a central portion of the substrate 210. The TSV 212 may electrically connect the conductive pad 120 to the element layer 270. The TSV 212 may have a columnar shape or a tapered shape in a cross section of which one end is smaller than the other end. Although not shown, an insulating layer may be formed in the substrate 210 to surround an outer side of the TSV 212. The insulating layer may insulate the TSV 212 from the substrate 210. The TSV 212 may include, for example, copper (Cu), silver (Ag), or tin (Sn).

The under bump metals 230, the bump structures 240, and the encapsulant 250 may be disposed under the element layer 270. The under bump metal 230 may be electrically connected to the TSV 212 through the element layer 270. The bump structure 240 may be disposed under the under bump metal 230. The bump structure 240 may have a planarized lower surface, and the lower surface of the bump structure 240 may be exposed to the outside. The bump structure 240 may include a connecting member 242 and a delamination prevention layer 244. The delamination prevention layer 244 may be disposed under the connecting member 242. The delamination prevention layer 244 may have a greater hardness than the connecting member 242. The delamination prevention layer 244 may include an IMC. The encapsulant 250 may be disposed on a lower surface of the substrate 210 and side surfaces of the bump structures 240, and may surround the bump structures 240. The encapsulant 250 may be planarized, and a lower surface of the encapsulant 250 may be coplanar with the lower surfaces of the bump structures 240.

The element layer 270 may be disposed under the substrate 210. The element layer 270 may include interconnection structures 272 therein. An insulating layer may be disposed along the element layer 270 to cover the interconnection structures 272. The interconnection structure 272 may include a plurality of metal layers which are disposed parallel to the lower surface of the substrate 110, and vias which connect metal layers positioned on different levels. Further, although not shown, the element layer 270 may include a plurality of elements therein. The metal layer of the interconnection structure 272 may provide a signal transmission path. The via may electrically connect the metal layers formed on different levels. The via may include a conductive material, and have a tapered or cylindrical shape. The via may be integrally formed with the metal layer. The metal layer and the via may include a conductive material (e.g., Cu, Al, Ag, Sn, Au, Ni, Pb, or Ti, or an alloy thereof).

As shown in FIG. 5, the semiconductor device 200 has the bump structures 240 and 245 thereabove and thereunder. The semiconductor device 200 may be connected to other semiconductor devices which are disposed thereabove and thereunder in a semiconductor package. The encapsulants 250 and 255 may be provided prior to mounting of the semiconductor device 200. The bump structures 240 and 245 may connect different semiconductor devices to each other.

Referring to FIG. 6, the semiconductor device 300 may include under bump metals 330, bump structures 340, an encapsulant 350, and an element layer 370, which are disposed under a substrate 310. The under bump metals 330, the bump structures 340, the encapsulant 350, and the element layer 370, which are shown in FIG. 6, may have technical features and structures identical or substantially similar to those of the under bump metals 230, the bump structures 240, the encapsulant 250, and the element layer 270, which are described in FIG. 5. Another semiconductor device may be connected to a lower portion of the semiconductor device 300 in a semiconductor package. The bump structures 340 may connect semiconductor devices to each other.

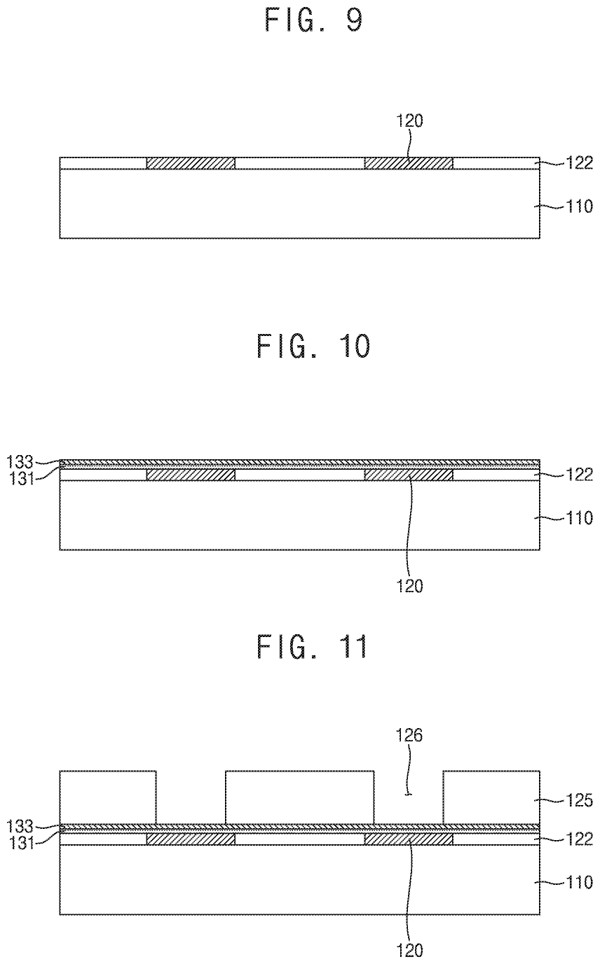

FIG. 7 is an enlarged cross-sectional view showing a portion of a semiconductor package 10 in which semiconductor devices are stacked according to an example embodiment of the inventive concepts.

Referring to FIG. 7, the semiconductor package 10 may include a first semiconductor device 100a and a second semiconductor device 100b. The second semiconductor device 100b may be stacked on the first semiconductor device 100a, and the first semiconductor device 100a and the second semiconductor device 100b may be disposed to face each other with a bonding interface 180 interposed therebetween.

The first semiconductor device 100a may include first conductive pads 120a, a first protective layer 122a, first under bump metals 130a, first bump structures 140a, and a first encapsulant 150a, which are disposed above a first substrate 110a. The first under bump metal 130a may include a first barrier layer 132a and a first seed layer 134a disposed on the first barrier layer 132a. The first bump structure 140a may include a first connecting member 142a and a first delamination prevention layer 144a disposed on the first connecting member 142a. The first encapsulant 150a may be disposed on an upper surface of the first substrate 110a and side surfaces of the first bump structures 140a, and may surround the first bump structures 140a.

The second semiconductor device 100b may include second conductive pads 120b, a second protective layer 122b, second under bump metals 130b, second bump structures 140b, and a second encapsulant 150b, which are disposed under a second substrate 110b. The second under bump metal 130b may include a second barrier layer 132b and a second seed layer 134b disposed under the second barrier layer 132b. The second bump structures 140b may include a second connecting member 142b and a second delamination prevention layer 144b disposed under the second connecting member 142b. The second encapsulant 150b may be disposed on a lower surface of the second substrate 110b and side surfaces of the second bump structures 140b, and may surround the second bump structures 140b. The second semiconductor device 100b may have technical features identical or substantially similar to those of the first semiconductor device 100a.

The second semiconductor device 100b may be stacked on the first semiconductor device 100a. An upper surface of the first semiconductor device 100a may be disposed to face a lower surface of the second semiconductor device 100b. The first bump structure 140a may be bonded to the second bump structure 140b, and the first encapsulant 150a may be bonded to the second encapsulant 150b. In an example embodiment, the first delamination prevention layer 144a may be bonded to the second delamination prevention layer 144b.

As shown in FIG. 7, when the first semiconductor device 100a and the second semiconductor device 100b are bonded, the first encapsulant 150a and the second encapsulant 150b may be provided. For example, the bonding may include a pressing process and a heating process. The heating process may be performed at a heating temperature of 300° C. or lower for about five minutes.

The bonding interface 180 may refer to a surface on which the first semiconductor device 100a and the second semiconductor device 100b are in contact with each other. The first semiconductor device 100a and the second semiconductor device 100b may be disposed to face each other at the bonding interface 180 interposed therebetween. For example, the first semiconductor device 100a and the second semiconductor device 100b may be formed symmetrically with respect to the bonding interface 180. The first delamination prevention layer 144a and the second delamination prevention layer 144b may be formed symmetrically with respect to the bonding interface 180. As shown in FIG. 7, the bonding interface 180 refers to an interface between the first semiconductor device 100a and the second semiconductor device 100b. For example, the bonding interface 180 refers to an interface between the upper surface of the first semiconductor device 100a and the lower surface of the second semiconductor device 100b.

In the semiconductor package 10 according to the example embodiment of the inventive concepts, when the first semiconductor device 100a and the second semiconductor device 100b are bonded, the first encapsulant 150a, which surrounds the first bump structures 140a, and the second encapsulant 150b, which surrounds the second bump structures 140b, may be provided. Shapes of the first connecting member 142a and the second connecting member 142b may be maintained without being reflowed by the first encapsulant 150a and the second encapsulant 150b in the bonding process. In an example embodiment, a side surface of the first delamination prevention layer 144a and a side surface of the first connecting member 142a in the semiconductor package 10 may be coplanar. A side surface of the second delamination prevention layer 144b and a side surface of the second connecting member 142b may be coplanar.

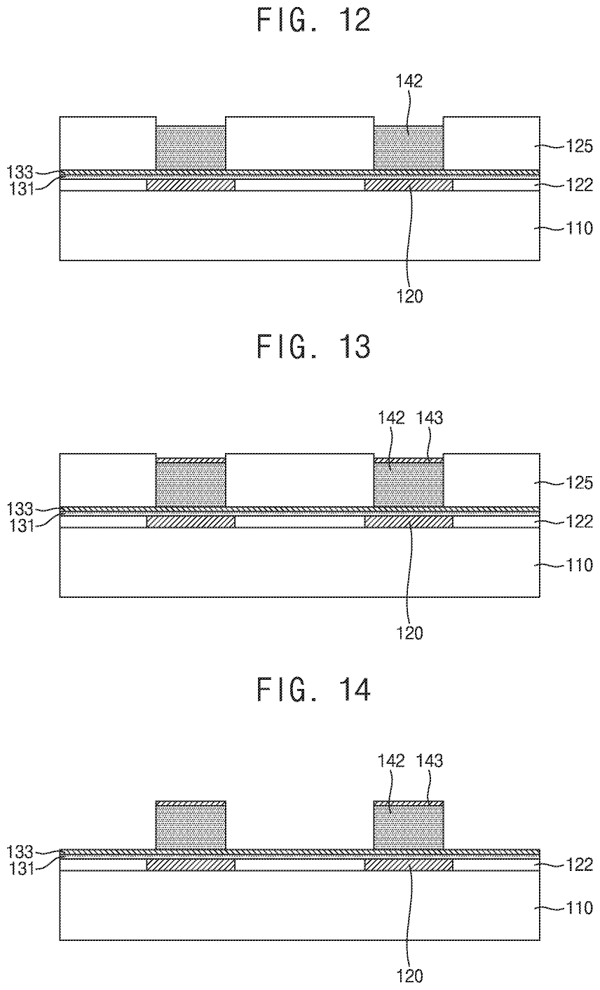

FIG. 8 is a cross-sectional view showing a portion of a semiconductor package in which semiconductor devices are stacked, according to another example embodiment of the inventive concepts.

Referring to FIG. 8, a semiconductor package 20 may include a first semiconductor device 100a and a third semiconductor device 100c. The third semiconductor device 100c may be stacked on the first semiconductor device 100a. The third semiconductor device 100c may include third conductive pads 120c, a third protective layer 122c, third under bump metals 130c, third bump structures 140c, and a third encapsulant 150c, which are disposed under a third substrate 110c. The third under bump metal 130c may include a third barrier layer 132c and a third seed layer 134c disposed under the third barrier layer 132c. The third bump structures 140c may include a third connecting member 142c and a third delamination prevention layer 144c disposed under the third connecting member 142c.

A height of the third connecting member 142c of the third semiconductor device 100c may be lower than a height of the first connecting member 142a. In FIG. 8, a thickness of the third delamination prevention layer 144c is shown as being substantially equal to a thickness of the first delamination prevention layer 144a, but the inventive concepts are not limited thereto. For example, the thickness of the third delamination prevention layer 144c may be smaller than the thickness of the first delamination prevention layer 144a. The first delamination prevention layer 144a and the third delamination prevention layer 144c may be disposed symmetrically with respect to a bonding interface 180.

The bonding interface 180 may be interposed between the first semiconductor device 100a and the third semiconductor device 100c. For example, the bonding interface 180 may be positioned at a higher level than an upper end of the first conductive pad 120a and at a lower level than a lower end of the second conductive pad 120c. In FIG. 8, the bonding interface 180 is shown as being positioned closer to the third semiconductor device 100c than the first semiconductor device 100a. However, in an example embodiment, the bonding interface 180 may be positioned closer to the first semiconductor device 100a than the third semiconductor device 100c.

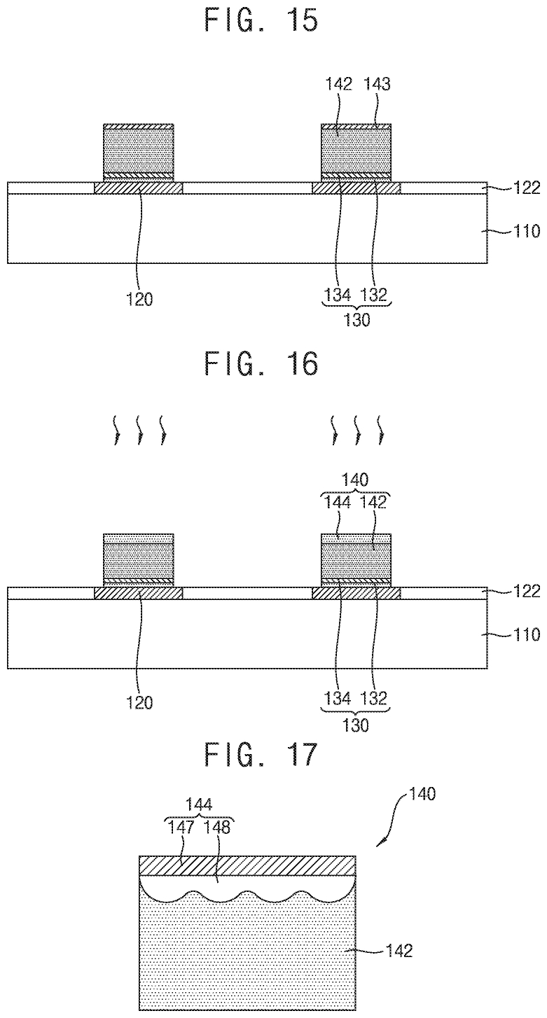

FIGS. 9 to 18 are cross-sectional views showing a process sequence for describing a method of manufacturing a semiconductor device 100 according to an example embodiment of the inventive concepts.

Referring to FIG. 9, conductive pads 120 and a protective layer 122 may be disposed on a substrate 110.

The substrate 110 may include a semiconductor such as silicon (Si) or germanium (Ge), a compound semiconductor, or a combination thereof. The plurality of conductive pads 120 may be disposed on an upper surface of the substrate 110. The protective layer 122 may cover the upper surface of the substrate 110 and may be disposed on side surfaces of the conductive pads 120. The conductive pad 120 may include W, Ti, TiN, Ta, TaN, Ni, Co, Mn, Al, Ag, Au, Cu, Sn, conductive carbon, or a combination thereof. In an example embodiment of the inventive concepts, the conductive pad 120 may include copper. The protective layer 122 may include an insulating material, and may include, for example, silicon nitride, silicon oxide, or polyimide.

Referring to FIG. 10, a barrier layer 131 and a seed layer 133 may be disposed on the conductive pads 120 and the protective layer 122. The seed layer 133 may be formed on the barrier layer 131.

The barrier layer 131 may include at least one selected from among Ta, Ti, W, Ru, V, Co, and Nb. For example, the barrier layer 131 may be made of tantalum nitride, tantalum silicide, tantalum carbide, titanium nitride, titanium silicide, titanium carbide, tungsten nitride, tungsten silicide, tungsten carbide, ruthenium, ruthenium oxide, vanadium oxide, cobalt oxide, niobium oxide, or the like. The seed layer 133 may include at least one selected from among Al, Ti, Cr, Fe, Co, Ni, Cu, Zn, Pd, Pt, Au, and Ag. In an example embodiment of the inventive concepts, the barrier layer 131 may include titanium, and the seed layer 133 may include copper. The barrier layer 131 and the seed layer 133 may be deposited by, for example, a physical vapor deposition (PVD) process, a chemical vapor deposition (CVD) process, or an atomic layer deposition (ALD) process.

Referring to FIG. 11, a mask pattern 125 having a plurality of openings 126 may be disposed on the seed layer 133. In a process of forming the openings 126, a photosensitive material may be deposited on the seed layer 133, a process of forming a mask may be performed thereon by a thermal treatment process, and an exposure process and a development process may be performed on the mask. The openings 126 may expose a portion of the seed layer 133 and, for example, may expose a portion of the seed layer 133 positioned on the conductive pad 120. The openings 126 may define regions in which the bump structures 140 are to be formed.

Referring to FIG. 12, a connecting member 142 may be disposed on the seed layer 133 in the opening 126. The connecting member 142 may be formed by a plating process and may include tin. An upper end of the connecting member 142 may be positioned at a lower level than an upper end of the mask pattern 125. A thickness of the connecting member 142 may be greater than a thickness of the barrier layer 131 and the seed layer 133. The connecting member 142 may have a cylindrical shape, a rectangular parallelepiped shape, or a tapered shape in which a sectional area narrows toward a lower portion. The connecting member 142 may be electrically connected to the conductive pad 120 through the barrier layer 131 and the seed layer 133. In an example embodiment, an IMC may be formed on a lower end of the connecting member 142 by a reaction with the barrier layer 131 and the seed layer 133. The IMC may a Cu—Sn based compound.

Referring to FIG. 13, a metal layer 143 may be disposed on the connecting member 142 in the opening 126. The metal layer 143 may be formed by plating a metal on the connecting member 142. The metal layer 143 may include a material having a greater hardness than the connecting member 142. In an example embodiment, the metal layer 143 may include copper, gold, silver, or a combination thereof. A thickness of the metal layer 143 may be smaller than the thickness of the connecting member 142, and may be greater than thicknesses of the barrier layer 131 and the seed layer 133. A horizontal width of the metal layer 143 may be substantially equal to a horizontal width of the connecting member 142. For example, a side surface of the metal layer 143 may be coplanar with a side surface of the connecting member 142.

Referring to FIG. 14, the mask pattern 125 may be removed. A portion of an upper surface of the seed layer 133 may be exposed, and the side surfaces of the connecting member 142 and the metal layer 143 may be exposed. The side surfaces of the connecting member 142 and the metal layer 143 may be substantially coplanar.

Referring to FIG. 15, portions of the barrier layer 131 and the seed layer 133 may be removed, and under bump metals 130 may be formed. The under bump metal 130 may be disposed under the connecting member 142 and may include a barrier layer pattern 132 and a seed layer pattern 134 disposed on the barrier layer pattern 132. In FIG. 5, horizontal widths of the barrier layer 132 and the seed layer 134 are shown to be equal to or substantially similar to the horizontal width of the connecting member 142. However, the horizontal width of the barrier layer 132 or the seed layer 134 may be smaller than the horizontal width of the connecting member 142.

Referring to FIG. 16, bump structures 140 may be formed by a thermal treatment process. The bump structure 140 may include the connecting member 142 and a delamination prevention layer 144 disposed on the connecting member 142. The delamination prevention layer 144 may be an IMC formed by a reaction of the metal layer 143 and the connecting member 142 by a thermal treatment process. The thermal treatment process may be performed at a temperature of 200° C. or lower for about ten minutes. The thermal treatment process may promote diffusion of a metal material contained in the metal layer 143 to grow the IMC. In FIG. 16, the entire metal layer 143 is shown as being phase-transitioned to the IMC to form the delamination prevention layer 144. However, in an example embodiment, an unreacted metal layer 143 may remain on the delamination prevention layer 144. Further, in an example embodiment, the delamination prevention layer 144 may be an IMC formed by a natural reaction between the metal layer 143 and the connecting member 142. The thermal treatment process may not reflow the connecting member 142, and a shape of the connecting member 142 may not be changed by the thermal treatment process. The connecting member 142 may have the same or substantially similar horizontal width as the barrier layer 132, the seed layer 134, and the delamination prevention layer 144. For example, the side surface of the connecting member 142 may be coplanar with the side surface of the delamination prevention layer 144, and the side surface of the connecting member 142 may be coplanar with side surfaces of the barrier layer 132 and the seed layer 134.

In an example embodiment, a thermal treatment process may be performed prior to forming of the metal layer 143 and removing of the mask pattern 125. The removal process of the barrier layer 131 and the seed layer 133 may be performed after the thermal treatment process.

FIG. 17 is an enlarged cross-sectional view showing a portion of the semiconductor device according to the example embodiment of the inventive concepts. FIG. 17 may correspond to the bump structures 140 shown in FIG. 16.

Referring to FIG. 17, the delamination prevention layer 144 may be formed as a multilayer. The multilayer may be IMC layers 147 and 148 having different phases. For example, when the delamination prevention layer 144 includes a Cu—Sn based IMC, the IMC layer 147 may include Cu₃Sn₄, and the IMC layer 148 may include Cu₆Sn₅. The IMC layer 147 may be positioned on an upper end of the delamination prevention layer 144 and may have a band shape (e.g., a flat strip shape). The IMC layer 148 may be positioned under the delamination prevention layer 144 and may have a scallop shape (meaning having a wave shape interface). In an example embodiment, the delamination prevention layer 144 may be formed only as either the IMC layer 147 or the IMC layer 148.

Referring to FIG. 18, an encapsulant 152 may be disposed to cover the upper surface of the substrate 110. The encapsulant 152 may seal the upper surface of the substrate 110 and upper surfaces and the side surfaces of the bump structures 140. The encapsulant 152 may be formed by a process such as spin coating or the like. An upper surface of the encapsulant 152 may have protrusions. For example, a portion of the encapsulant 152, which is positioned on the bump structures 140, may be formed at a level higher than a portion of the encapsulant 152, which is positioned on the protective layer 122. The encapsulant 152 may protect the bump structures 140 from external impact. The encapsulant 152 may be a resin containing an epoxy or polyimide. For example, the encapsulant 152 may be, for example, a bisphenol-group epoxy resin, a polycyclic aromatic epoxy resin, an o-cresol novolac epoxy resin, a biphenyl-group epoxy resin, or a naphthalene-group epoxy resin. In an example embodiment, the encapsulant 152 may include an EMC.

Referring to FIG. 2, an upper portion of the encapsulant 152 may be partially removed by a planarization process. Chemical mechanical polishing (CMP) or fly cutting may be used as the planarization process. An upper portion of the delamination prevention layer 144 may be partially removed by the planarization process. The delamination prevention layer 144 may be exposed to the outside by the planarization process, and the upper end of the delamination prevention layer 144 may be positioned at the same level as an upper end of the encapsulant 150. For example, the upper surface of the delamination prevention layer 144 may be coplanar with the upper surface of the encapsulant 150.

Because the encapsulant 150 is cured by heat while forming the encapsulant 150, the encapsulant 150 may have a greater hardness than the connecting member 142. In the planarization process, a cut portion of the connecting member 142 having a smaller hardness may be delaminated, and delaminated burrs may be disposed between the bump structures 140. When the connecting member 142 is delaminated, a width of the connecting member 142 is reduced, and thus a reliability problem may occur in the stacking of the semiconductor device 100. When the burrs are generated, a problem may occur in that the connecting members 142 in which the burrs are spaced apart from each other are electrically connected to each other.

As shown in FIGS. 2 and 18, when the delamination prevention layer 144 is formed on an upper portion of the bump structure 140, the delamination prevention layer 144 having a lower hardness than the connecting member 142 may not be damaged by the planarization process. The delamination prevention layer 144 may protect the connecting member 142, and thus occurrence of a reliability problem of the bump structure 140 may be mitigated or prevented.

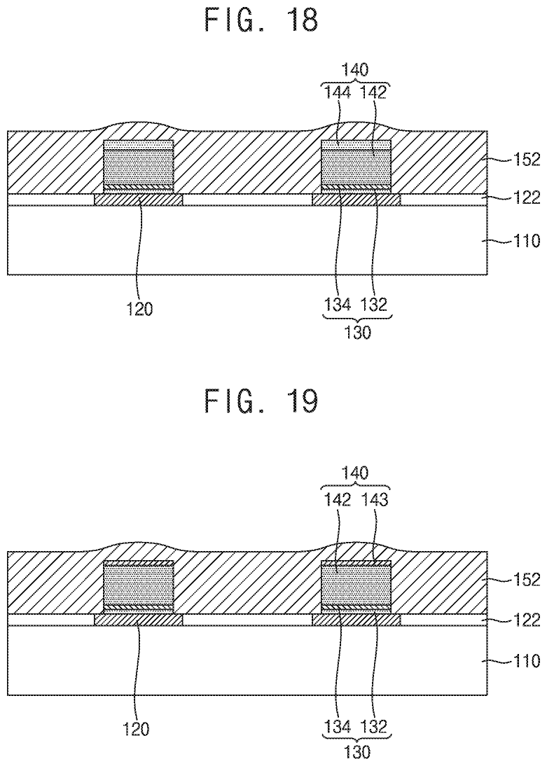

FIGS. 19 ad 20 are cross-sectional views showing a process sequence for describing a method of manufacturing a semiconductor device 100 according to an example embodiment of the inventive concepts. FIG. 19 may correspond to FIG. 18, and FIG. 20 may correspond to FIG. 2.

Referring to FIGS. 16 and 19, the thermal treatment process for heating the metal layer 143 may be omitted. The delamination prevention layer 144 containing an IMC may not be formed from the metal layer 143, and the encapsulant 152 which covers the upper surface of the substrate 110 may be formed. Referring to FIG. 20, an upper portion of the encapsulant 152 may be partially removed by a planarization process. The metal layer 143 may be exposed to the outside by the planarization process, and an upper end of the metal layer 143 may be positioned at the same level as an upper end of the encapsulant 150. For example, an upper surface of the metal layer 143 may be coplanar with an upper surface of the encapsulant 150.

As shown in FIGS. 19 and 20, a molding process and a planarization process may be performed on the metal layer 143 without performing a thermal treatment process on the metal layer 143. The metal layer 143 having a greater hardness than the connecting member 142 may protect the connecting member 142, and mitigate or prevent the connecting member 142 from being delaminated in the planarization process. In FIGS. 19 and 20, only the metal layer 143 is shown as being disposed on the connecting member 142. However, an IMC may be formed on a lower portion of the metal layer 143 by diffusion without performing the thermal treatment process. The IMC may also mitigate or prevent the connecting member 142 from being delaminated in the planarization process.

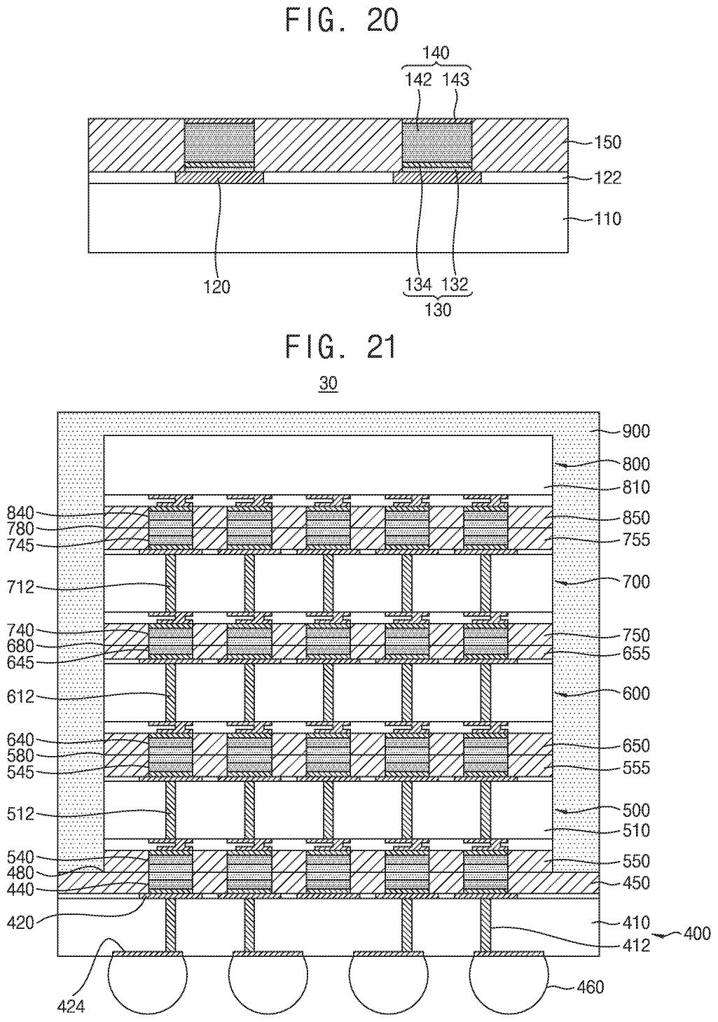

FIG. 21 is a cross-sectional view showing a semiconductor package 30 according to an example embodiment of the inventive concepts.

Referring to FIG. 21, the semiconductor package 30 may have a structure in which semiconductor devices 400, 500, 600, 700, and 800 are stacked. The semiconductor package 30 may include a first semiconductor device 400, a second semiconductor device 500, a third semiconductor device 600, a fourth semiconductor device 700, a fifth semiconductor device 800, and an external encapsulant 900, which are sequentially stacked.

The first semiconductor device 400 may correspond to the semiconductor device 100 shown in FIG. 1. The first semiconductor device 400 may include a first substrate 410, interconnection structures 412, conductive pads 420 and 424, bump structures 440, an encapsulant 450, and external terminals 460.

The interconnection structures 412 may be disposed inside the first substrate 410. The interconnection structure 412 may electrically connect the conductive pads 420 and 424. The conductive pads 420 may be disposed on an upper surface of the first substrate 410, and the conductive pads 424 may be disposed on a lower surface of the first substrate 410. The bump structures 440 may be disposed on the conductive pads 420 and 424, and the encapsulant 450 may be disposed to surround the bump structures 440.

The second semiconductor device 500 may correspond to the semiconductor device 200 shown in FIG. 5. The second semiconductor device 500 may be stacked on the first semiconductor device 400. The second semiconductor device 500 may include a second substrate 510, TSVs 512, lower bump structures 540, upper bump structures 545, a lower encapsulant 550, and an upper encapsulant 555.

The TSVs 512 may be formed in the second substrate 510 and may be disposed in a central region of the second substrate 510. The TSV 512 may be formed to vertically pass through at least a portion of the second substrate 510, and may electrically connect the lower bump structure 540 to the upper bump structure 545. The lower bump structure 540 may be bonded to the bump structure 440 of the first semiconductor device 400.

The third semiconductor device 600 may correspond to the semiconductor device 200 shown in FIG. 5. The third semiconductor device 600 may be stacked on the second semiconductor device 500. The third semiconductor device 600 may include a third substrate 610, TSVs 612, lower bump structures 640, upper bump structures 645, a lower encapsulant 650, and an upper encapsulant 655.

The fourth semiconductor device 700 may correspond to the semiconductor device 200 shown in FIG. 5. The fourth semiconductor device 700 may be stacked on the third semiconductor device 600. The fourth semiconductor device 700 may include a fourth substrate 710, TSVs 712, lower bump structures 740, upper bump structures 745, a lower encapsulant 750, and an upper encapsulant 755.

The third semiconductor device 600 and the fourth semiconductor device 700 may have technical features identical or substantially similar to those of the second semiconductor device 500. Detailed descriptions of the third semiconductor device 600 and the fourth semiconductor device 700 may be omitted.

The fifth semiconductor device 800 may correspond to the semiconductor device 300 shown in FIG. 6. The fifth semiconductor device 800 may be stacked on the fourth semiconductor device 700. The fifth semiconductor device 800 may include a fifth substrate 810, bump structures 840, and an encapsulant 850.

The stacking process may be performed stepwise. For example, after the second semiconductor device 500 is stacked on the first semiconductor device 400, the third semiconductor device 600 may be stacked on the second semiconductor device 500. Each of the fourth semiconductor device 700 and the fifth semiconductor device 800 may be stacked in the same manner. Upon completion of the stacking process, the external encapsulant 900 may be further disposed to cover the first semiconductor device 400, the second semiconductor device 500, the third semiconductor device 600, the fourth semiconductor device 700, and the fifth semiconductor device 800. The external encapsulant 900 may include the same material as each of the encapsulants 450, 550, 555, 650, 655, 750, 755, and 850, and may include, for example, an EMC.

Bonding interfaces 480, 580, 680, and 780 may be formed between the first semiconductor device 400 and the second semiconductor device 500, between the second semiconductor device 500 and the third semiconductor device 600, between the third semiconductor device 600 and the fourth semiconductor device 700, and between the fourth semiconductor device 700 and the fifth semiconductor device 800, respectively. The bump structure 440 and the lower bump structure 540, the upper bump structure 545 and the lower bump structure 640, the upper bump structure 645 and the lower bump structure 740, and the upper bump structure 745 and the bump structure 840 may be disposed symmetrically with respect to the bonding interfaces 480, 580, 680, and 780, respectively. As shown in FIGS. 1, 5, and 6, each of the bump structures 140 may include the delamination prevention layer 144. The delamination prevention layer 144 may be disposed to surround the bonding interface 180.

The first semiconductor device 400 may be a logic chip, and the second semiconductor device 500, the third semiconductor device 600, the fourth semiconductor device 700, and the fifth semiconductor device 800 may be memory chips, (e.g., dynamic random access memories (DRAMs), static random access memories (SRAMs), or phase-change memories (PRAMs)). In an example embodiment, the second to fifth semiconductor devices 800 may be high bandwidth memories (HBMs) or DRAMs.

The interconnection structures 412 and the TSVs 512, 612, and 712 may provide electrical signals between the first to fifth semiconductor devices 400, 500, 600, 700, and 800. The external terminals 460 may receive electrical signals from an external device. For example, the external terminals 460 may receive a power supply signal, a ground signal, or a control signal for operations of the first to fifth semiconductor devices 400, 500, 600, 700, and 800. Further, the external terminals 460 may receive data signals which will be stored in the second to fifth semiconductor devices 500, 600, 700, and 800, or may provide data signals which are stored in the second to fifth semiconductor devices 500, 600, 700, and 800 to the external device.

According to the disclosed example embodiments of the inventive concepts, a metal layer can be disposed on a connecting member. A delamination prevention layer including an IMC can be formed from the metal layer by a thermal treatment process. The delamination prevention layer having a relatively high hardness can mitigate or prevent the connecting member from being delaminated in a planarization process. The delamination prevention layer can protect the connecting member and thus a semiconductor device with improved reliability can be implemented.

While the some example embodiments of the inventive concepts have been described with reference to the accompanying drawings, it should be understood by those skilled in the art that various modifications may be made without departing from the scope of the inventive concepts and without changing essential features thereof. Therefore, the above-described example embodiments should be considered in a descriptive sense only and not for purposes of limitation.

What is claimed is:

1. A semiconductor device comprising:
a substrate including a first conductive pad on a first surface thereof;
at least one first bump structure on the first conductive pad, the first bump structure including a first connecting member and a first delamination prevention layer, the first delamination prevention layer on the first connecting member and having a greater hardness than the first connecting member; and
a first encapsulant above the first surface of the substrate and surrounding the first bump structure.

2. The semiconductor device of claim 1, wherein the first delamination prevention layer comprises an intermetallic compound.

3. The semiconductor device of claim 2, wherein the intermetallic compound comprises a Cu—Sn based intermetallic compound, an Au-Sn based intermetallic compound, or a combination thereof.

4. The semiconductor device of claim 1, wherein the first bump structure further comprises a metal layer disposed on an upper surface of the first delamination prevention layer.

5. The semiconductor device of claim 1, wherein an upper surface of the first delamination prevention layer is exposed to an outside of the first encapsulant.

6. The semiconductor device of claim 1, wherein a thickness of the first delamination prevention layer is smaller than a thickness of the first connecting member.

7. The semiconductor device of claim 1, wherein
an upper surface of the first delamination prevention layer and an upper surface of the first encapsulant are coplanar, and
a side surface of the first delamination prevention layer and a side surface of the first connecting member are coplanar.

8. The semiconductor device of claim 1, wherein the at least one first bump structure includes a plurality of first bump structures that are spaced apart from each other at a distance of 15 μm to 30 μm.

9. The semiconductor device of claim 1, further comprising:
a second conductive pad on a second surface of the substrate, the second surface opposite to the first surface; and
at least one second bump structure on the second conductive pad, the second bump structure including a second connecting member and a second delamination prevention layer, the second delamination prevention layer on the second connecting member and having a greater hardness than the second connecting member.

10. The semiconductor device of claim 9, further comprising:
a through silicon via penetrating the substrate and electrically connecting the first conductive pad to the second conductive pad.

11. A semiconductor package comprising:
a first semiconductor device including a first conductive pad, at least one first bump structure on the first conductive pad, and a first encapsulant surrounding the first bump structure, which are sequentially stacked on an upper surface of a first substrate, the first bump structure including a first connecting member and a first delamination prevention layer, the first delamination prevention layer on the first connecting member and having a greater hardness than the first connecting member, a side surface of the first delamination prevention layer and a side surface of the first connecting member being coplanar; and
a second semiconductor device including a second conductive pad, at least one second bump structure under the second conductive pad, a second encapsulant surrounding the second bump structure, which are sequentially stacked on a lower surface of a second substrate, the second bump structure including a second connecting member and a second delamination prevention layer, the second delamination prevention layer on the second connecting member and having a greater hardness than the second connecting member, a side surface of the second delamination prevention layer and a side surface of the second connecting member being coplanar, the second bump structure being in contact with the first bump structure.

12. The semiconductor package of claim 11, wherein the side surface of the first connecting member and the side surface of the second connecting member are coplanar.

13. The semiconductor package of claim 11, wherein a distance between the first delamination prevention layer and the first substrate is equal to a distance between the second delamination prevention layer and the second substrate.

14. The semiconductor package of claim 11, wherein a distance between the first delamination prevention layer and the first substrate is greater than a distance between the second delamination prevention layer and the second substrate.

15. The semiconductor package of claim 11, wherein
a thickness of the first delamination prevention layer is smaller than a thickness of the first connecting member, and
a thickness of the second delamination prevention layer is smaller than a thickness of the second connecting member.

16. The semiconductor package of claim 11, wherein the at least one first bump structure and the at least one second bump structure include a plurality of first bump structures and a plurality of second bump structures, respectively, and each group of the plurality of first bump structures and the plurality of second bump structures are spaced from each other at a distance of 15 μm to 30 μm.

17. The semiconductor package of claim 11, wherein the first delamination prevention layer and the second delamination prevention layer each comprise an intermetallic compound.

18. A semiconductor package comprising:
a plurality of stacked semiconductor devices, each of the plurality of stacked semiconductor devices including,
a substrate including conductive pads on one surface or two opposite surfaces thereof,
bump structures each including a connecting member and a delamination prevention layer, the delamination prevention layer being on the connecting member and having a greater hardness than the connecting member, and
one or more inner encapsulants on the one surface or the two opposite surfaces of the substrate and surrounding the bump structures,
each of the plurality of stacked semiconductor devices being in contact with and immediately adjacent to one or more of the plurality of stacked semiconductor devices; and
an external encapsulant sealing the plurality of stacked semiconductor devices.

19. The semiconductor package of claim 18, wherein a side surface of each of the delamination prevention layers is coplanar with a side surface of each of the connecting members.

20. The semiconductor package of claim 18, wherein the delamination prevention layers each comprise an intermetallic compound.
